(19) United States
(12) Patent Application Publication
(10) Pub. No.: US 2009/0127715 A1
(43) Pub. Date: May 21, 2009

(54) MOUNTABLE INTEGRATED CIRCUIT PACKAGE SYSTEM WITH PROTRUSION

(76) Inventors: HanGil Shin, Ichon-si (KR); In Sang Yoon, Ichon-si (KR); Jae Han Chung, Ichon-si (KR)

Correspondence Address: LAW OFFICES OF MIKIO ISHIMARU, 333 W. EL CAMINO REAL, SUITE 330, SUNNYVALE, CA, 94087, US

(21) Appl. No.: 11/940,969

(22) Filed: Nov. 15, 2007

(51) Int. Cl. H01L 23/50

(52) U.S. Cl. 257/777; 257/E23.079

(57) ABSTRACT

A mountable integrated circuit package system includes: mounting a first integrated circuit device over a carrier; mounting a second integrated circuit device over the first integrated circuit device includes: attaching the second integrated circuit device to a first substrate side of a substrate, and connecting a first electrical interconnect between the second integrated circuit device and a second substrate side of the substrate through an opening in the substrate. The mountable integrated circuit package system further including: forming a package encapsulation over the first integrated circuit device and the carrier with the substrate partially exposed.

### TECHNICAL FIELD

The present invention relates generally to integrated circuit package system and more particularly to an integrated circuit package system having an encapsulation.

### BACKGROUND ART

Integrated circuit packaging technology has seen an increase in the number of integrated circuits mounted on a single circuit board or substrate. The new packaging designs are more compact in form factors, such as the physical size and shape of an integrated circuit, and providing a significant increase in overall integrated circuit density. However, integrated circuit density continues to be limited by the “real estate” available for mounting individual integrated circuits on a substrate. Even larger form factor systems, such as personal computers, compute servers, and storage servers, need more integrated circuits in the same or smaller “real estate”. Particularly acute, the needs for portable personal electronics, such as cell phones, digital cameras, music players, personal digital assistants, and location-based devices, have further driven the need for integrated circuit density.

This increased integrated circuit density has led to the development of multi-chip packages, a package in package (PIP), a package on package (POP), or a combination thereof in which more than one integrated circuit can be packaged. Each package provides mechanical support for the individual integrated circuits and one or more layers of interconnect lines that enable the integrated circuits to be connected electrically to surrounding circuitry. Current multi-chip packages, also commonly referred to as multi-chip modules, typically consist of a substrate onto which a set of separate integrated circuit components are attached. Such multi-chip packages have been found to increase integrated circuit density and miniaturization, improve signal propagation speed, reduce overall integrated circuit size and weight, improve performance, and lower costs all of which are primary goals of the computer industry.

Thus, a need still remains for an integrated circuit package system providing low cost manufacturing, improved yield, and thinner height for the integrated circuits. In view of the ever-increasing need to save costs and improve efficiencies, it is more and more critical that answers be found to these problems.

Solutions to these problems have been long sought but prior developments have not taught or suggested any solutions and, thus, solutions to these problems have long eluded those skilled in the art.

### DISCLOSURE OF THE INVENTION

The present invention provides a mountable integrated circuit package system including: mounting a first integrated circuit device over a carrier; mounting a second integrated circuit device over the first integrated circuit device includes: attaching the second integrated circuit device to a first substrate side of a substrate, and connecting a first electrical interconnect between the second integrated circuit device and a second substrate side of the substrate through an opening in the substrate. The integrated circuit package system further including: forming a package encapsulation over the first integrated circuit device and the carrier with the substrate partially exposed.

Certain embodiments of the invention have other aspects in addition to or in place of those mentioned or obvious from the above. The aspects will become apparent to those skilled in the art from a reading of the following detailed description when taken with reference to the accompanying drawings.

### BRIEF DESCRIPTION OF THE DRAWINGS

FIG. 1 is a top view of a mountable integrated circuit package system in a first embodiment of the present invention;

FIG. 2 is a cross-sectional view of the mountable integrated circuit package system of FIG. 1 along line 2-2;

FIG. 3 is a top view of the substrate of the mountable integrated circuit package system of FIG. 1;

FIG. 4 is a cross-sectional view of a mountable integrated circuit package system as exemplified by the top view of FIG. 1 in a second embodiment of the present invention;

FIG. 5 is a top view of a mountable integrated circuit package system in a third embodiment of the present invention;

FIG. 6 is a cross-sectional view of the mountable integrated circuit package system of FIG. 5 along line 6-6;

FIG. 7 is a top view of the substrate of the mountable integrated circuit package system of FIG. 5;

FIG. 8 is a top view of a mountable integrated circuit package system in a fourth embodiment of the present invention;

FIG. 9 is a cross-sectional view of the mountable integrated circuit package system of FIG. 8 along line 9-9;

FIG. 10 is a cross-sectional view of a mountable integrated circuit package system as exemplified by the top view of FIG. 7 in a fifth embodiment of the present invention;

FIG. 11 is a top view of an integrated circuit package-on-package system in an application with the mountable integrated circuit package system in a sixth embodiment of the present invention;

FIG. 12 is a cross-sectional view of the integrated circuit package on package system of FIG. 11 along line 12-12; and

FIG. 13 is a flow chart of a mountable integrated circuit package system for manufacture of the mountable integrated circuit package system in an embodiment of the present invention.

### BEST MODE FOR CARRYING OUT THE INVENTION

The following embodiments are described in sufficient detail to enable those skilled in the art to make and use the invention. It is to be understood that other embodiments would be evident based on the present disclosure, and that system, process, or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known circuits, system configurations, and process steps are not disclosed in detail. Likewise, the drawings showing embodiments of the system are semi-diagrammatic and not to scale and, particularly, some of the dimensions are for the clarity of presentation and are shown greatly exaggerated in the drawing FIGs. Generally, the invention can be operated in any orientation.

In addition, where multiple embodiments are disclosed and described having some features in common, for clarity and ease of illustration, description, and comprehension thereof, similar and like features one to another will ordinarily be described with like reference numerals. The embodiments have been numbered first embodiment, second embodiment, etc. as a matter of descriptive convenience and are not intended to have any other significance or provide limitations for the present invention.

For expository purposes, the term “horizontal” as used herein is defined as a plane parallel to the plane or surface of the integrated circuit, regardless of its orientation. The term “vertical” refers to a direction perpendicular to the horizontal as just defined. Terms, such as “above”, “below”, “bottom”, “top”, “side” (as in “sidewall”), “higher”, “lower”, “upper”, “over”, and “under”, are defined with respect to the horizontal plane. The term “on” means there is direct contact among elements. The term “processing” as used herein includes deposition of material, patterning, exposure, development, etching, cleaning, molding, and/or removal of the material or as required in forming a described structure. The term “system” as used herein means and refers to the method and to the apparatus of the present invention in accordance with the context in which the term is used.

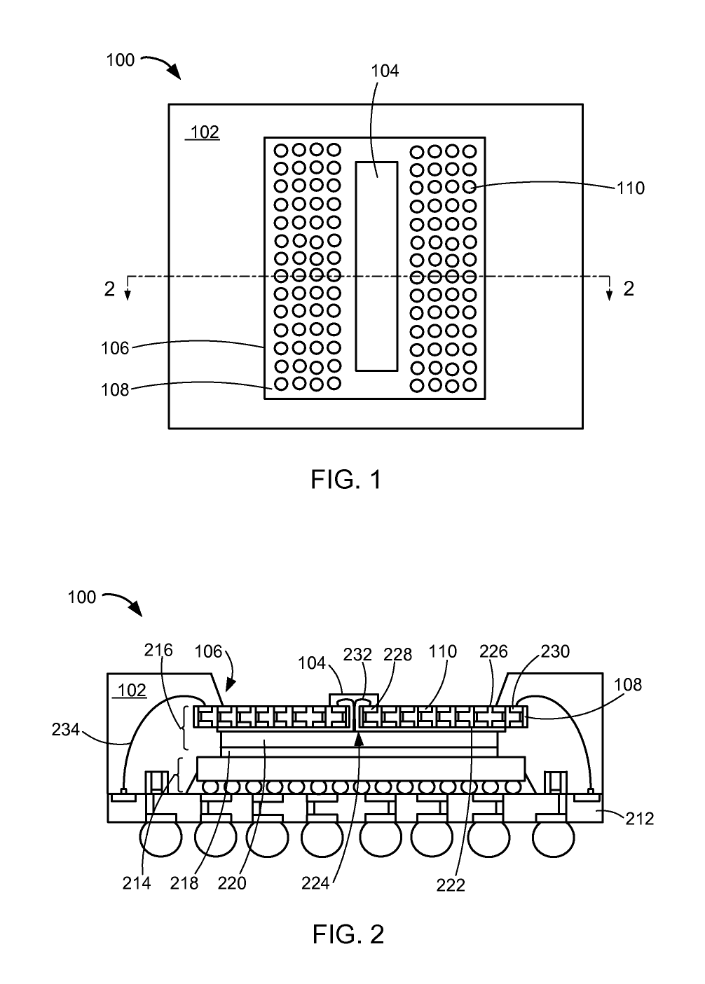

Referring now to FIG. 1, therein is shown a top view of a mountable integrated circuit package system 100 in a first embodiment of the present invention. The top view depicts a package encapsulation 102, such as an epoxy mold compound, having a protrusion 104 and a package cavity 106. The package cavity 106 partially exposes a substrate 108 having mounting contacts 110 and the protrusion 104 within the package cavity 106. The protrusion 104 is part of the package encapsulation 102. The mounting contacts 110 may be formed from electrically conductive materials including tin (Sn), lead (Pb), gold (Au), copper (Cu), or metal alloys.

For illustrative purposes, the mountable integrated circuit package system 100 is shown with the mounting contacts 110 in configurations of an evenly distributed array, although it is understood that the mountable integrated circuit package system 100 may have the mounting contacts 110 in a different configuration. For example, the mounting contacts 110 may be in configurations of a non-evenly distributed array.

Referring now to FIG. 2, therein is shown a cross-sectional view of the mountable integrated circuit package system 100 along 2-2 of FIG. 1. The cross-sectional view depicts the mountable integrated circuit package system 100 having the package encapsulation 102 formed over a carrier 212, such as a substrate, having mounted thereon a first integrated circuit device 214, such as an integrated circuit die, a flip chip, or a packaged integrated circuit device. A second integrated circuit device 216 is mounted over the first integrated circuit device 214 with a first adhesive 218, such as a die-attach adhesive.

As illustrated, the second integrated circuit device 216 includes an integrated circuit die 220 attached to a first substrate side 222 of the substrate 108, under an opening 224 of the substrate 108. A second substrate side 226 of the substrate 108, opposing the first substrate side 222, includes the mounting contacts 110, inner substrate contacts 228 along the opening 224 of the substrate 108, and outer substrate contacts 230. A first electrical interconnect 232, such as bond wires, connects the integrated circuit die 220 and the inner substrate contacts 228 on the second substrate side 226 through the opening 224. A second electrical interconnect 234, such as a bond wire, electrically connects the outer substrate contacts 230 to the carrier 212. The mounting contacts 110 provided connection to another integrated circuit device (not shown.)

The package encapsulation 102 partially exposes the second substrate side 226 within the package cavity 106 of the package encapsulation 102. The package encapsulation 102 covers the carrier 212, the first integrated circuit device 214, the second integrated circuit device 216, the second electrical interconnect 234, and forms the protrusion 104 over the second substrate side within the package cavity 106. The protrusion 104 encapsulates the first electrical interconnect 232 and the inner substrate contacts 228 adjacent the opening 224. The package encapsulation 102 partially exposes the second substrate side 226 with the mounting contacts 110 exposed within the package cavity 106.

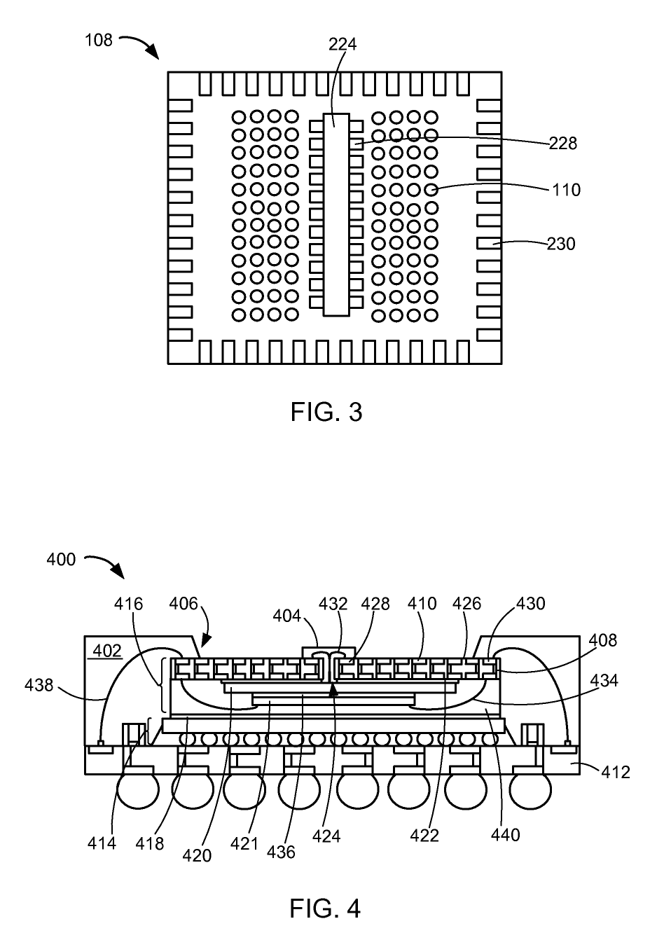

Referring now to FIG. 3, therein is shown a top view of the substrate 108 of the mountable integrated circuit package system 100 of FIG. 2. As shown, the second substrate side 226 of FIG. 2 includes the opening 224 with the inner substrate contacts 228, such as conductive metal pads, along the opening 224 for connection to the first electrical interconnect 232 of FIG. 2. The second substrate side 226 also includes the outer substrate contacts 230, such as conductive metal pads, for connection to the second electrical interconnect 234 of FIG. 2. The second substrate side 226 also includes the mounting contacts 110.

It has been discovered that the present invention provides a low profile mountable integrated circuit package system that minimized electrical failure during package assembly by connecting an integrated circuit die to a substrate with an electrical interconnect through an opening in the substrate, connecting between the integrated circuit die and inner substrate contacts adjacent to the opening in the substrate, encapsulated to form a protrusion exposed by a package encapsulation. This mountable integrated circuit package system further allows a single transfer molding process to reduce manufacturing cost.

Referring now to FIG. 4, therein is shown a cross-sectional view of a mountable integrated circuit package system 400 as exemplified by the top view of FIG. 1 in a second embodiment of the present invention. The cross-sectional view depicts the mountable integrated circuit package system 400 having a package encapsulation 402 formed over a carrier 412 such as a substrate, having mounted thereon a first integrated circuit device 414, such as an integrated circuit die, a flip chip, or a packaged integrated circuit device. A second integrated circuit device 416 is mounted over the first integrated circuit device 414 with a first adhesive 418 such as a die-attach adhesive.

As illustrated, the second integrated circuit device 416 includes a first integrated circuit die 420 attached to a first substrate side 422 of a substrate 408. The substrate 408 may have structural similarities to the substrate 108 of FIG. 1. A second substrate side 426 of the substrate 408, opposing the first substrate side 422, includes mounting contacts 410, inner substrate contacts 428 along an opening 424 of the substrate 408, and outer substrate contacts 430. A first electrical interconnect 432, such as bond wires, connects the first integrated circuit die 420 and the inner substrate contacts 428 on the second substrate side 426 through the opening 424. A second integrated circuit die 421 mounts to the first integrated circuit die 420 with a second adhesive 436, such as a die-attach adhesive. A second electrical interconnect 434, such as a bond wire, electrically connects the second integrated circuit die 421 and the first substrate side 422. A third electrical interconnect 438, such as a bond wire, connects the outer substrate contacts 430 and the carrier 412. The mounting contacts 410 provided connection to another integrated circuit device (not shown.)

The second integrated circuit device 416 includes an inner encapsulation 440, such as an epoxy molding compound. The inner encapsulation 440 is formed covering the first integrated circuit die 420, the second integrated circuit die 421, the first substrate side 422, the first electrical interconnect 432, and the second electrical interconnect 434. The inner encapsulation 440 also fills the opening 424 and is over the second substrate side 426 adjacent the opening 424. The inner encapsulation 440 forms a protrusion 404 over the second substrate side 426. The protrusion 404 encapsulates the first electrical interconnect 432 and the inner substrate contacts 428 on the second substrate side 426.

The package encapsulation 402 partially exposes the second substrate side 426 within a package cavity 406 of the package encapsulation 402. The package encapsulation 402 covers the carrier 412, the first integrated circuit device 414, the second integrated circuit device 416, and the third electrical interconnect 438. The package encapsulation 402 also covers the inner encapsulation 440 with the mounting contacts 410 and the protrusion 404 exposed.

It has been discovered that the present invention provides a low profile mountable integrated circuit package system that minimized electrical failure during package assembly by connecting a stack of integrated circuit dice to a substrate with electrical interconnects through an opening in the substrate, connecting between the stack of the integrated circuit dice and inner substrate contacts adjacent to the opening in the substrate as well as to both sides of the substrate, encapsulated to form a protrusion exposed by a package encapsulation. This mountable integrated circuit package system provides separate packaging process, such as to form a package-on-package device, allowing electrical testing during package assembly.

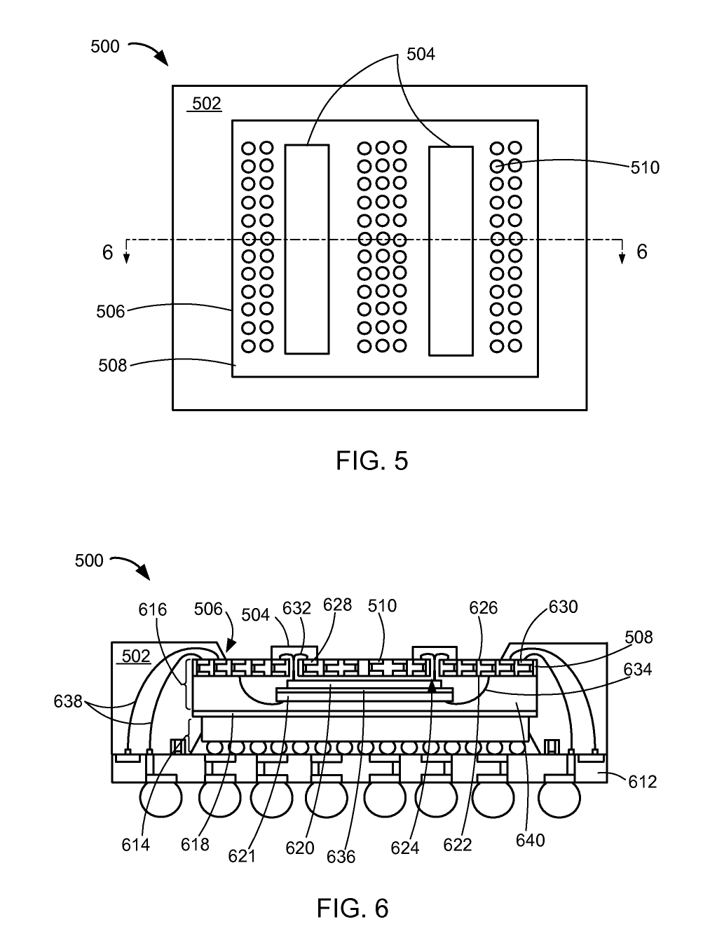

Referring now to FIG. 5, therein is shown a top view of a mountable integrated circuit package system 500 in a third embodiment of the present invention. The top view depicts a package encapsulation 502, such as an epoxy mold compound, having a package cavity 506. The package cavity 506 partially exposes a substrate 508 having mounting contacts 510 and protrusions 504 within the package cavity 506. The mounting contacts 510 may be formed from electrically conductive materials including tin (Sn), lead (Pb), gold (Au), copper (Cu), or metal alloys.

For illustrative purposes, the mountable integrated circuit package system 500 is shown with the mounting contacts 510 in configurations of an evenly distributed array, although it is understood that the mountable integrated circuit package system 500 may have the mounting contacts 510 in a different configuration. For example, the mounting contacts 510 may be in configurations of a non-evenly distributed array.

Referring now to FIG. 6, therein is shown a cross-sectional view of the mountable integrated circuit package system 500 of FIG. 5 along line 6-6. The cross-sectional view depicts the mountable integrated circuit package system 500 having the package encapsulation 502 formed over a carrier 612, such as a substrate, having mounted thereon a first integrated circuit device 614, such as an integrated circuit die, a flip chip, or a packaged integrated circuit device. A second integrated circuit device 616 is mounted over the first integrated circuit device 614 with a first adhesive 618 such as a die-attach adhesive.

As illustrated, the second integrated circuit device 616 includes a first integrated circuit die 620 attached to a first substrate side 622 of the substrate 508 having openings 624. A second substrate side 626 of the substrate, 508 opposing the first substrate side 622, includes the mounting contacts 510, inner substrate contacts 628 along each of the openings 624 of the substrate 508, and outer substrate contacts 630. A first electrical interconnect 632, such as bond wires, connects the first integrated circuit die 620 and the inner substrate contacts 628 on the second substrate side 626 through each of the openings 624. A second integrated circuit die 621 mounts to the first integrated circuit die 620 with a second adhesive 636, such as a die-attach adhesive. A second electrical interconnect 634, such as a bond wire, electrically connects the first substrate side 622 and the second integrated circuit die 621. A third electrical interconnect 638, such as a bond wire, connects the outer substrate contacts 630 and the carrier 612. The mounting contacts 510 provided connection to another integrated circuit device (not shown.)

The second integrated circuit device 616 includes an inner encapsulation 640, such as an epoxy molding compound. The inner encapsulation 640 is formed covering the first integrated circuit die 620, the second integrated circuit die 621, the first substrate side 622, the first electrical interconnect 632, and the second electrical interconnect 634. The inner encapsulation 640 also fills each of the openings 624 and is over the second substrate side 626 adjacent each of the openings 624. The inner encapsulation 640 forms the protrusions 504 over the second substrate side 626. Each of the protrusions 504 encapsulates the first electrical interconnect 632 and the inner substrate contacts 628 on the second substrate side 626 adjacent each of the openings 624.

The package encapsulation 502 partially exposes the second substrate side 626 within the package cavity 506 of the package encapsulation 502. The package encapsulation 502 covers the carrier 612, the first integrated circuit device 614, the second integrated circuit device 616, and the third electrical interconnect 638. The package encapsulation 502 also covers the inner encapsulation 640 with the mounting contacts 510 and the protrusions 504 exposed.

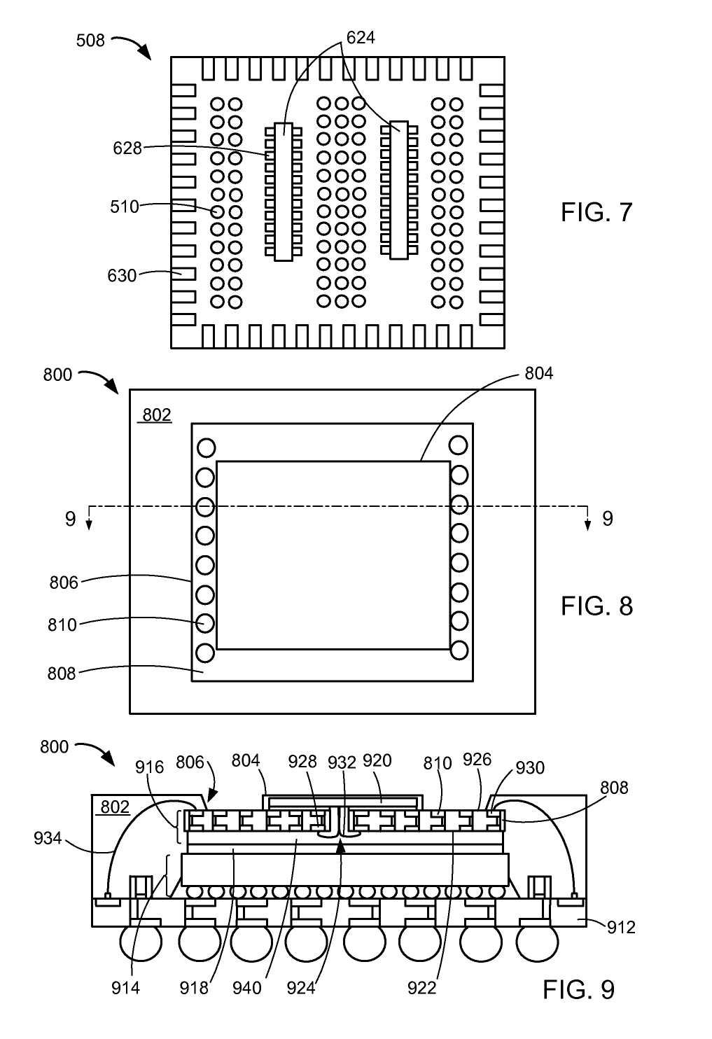

Referring now to FIG. 7, therein is shown a top view of the substrate 508 of the mountable integrated circuit package system 500 of FIG. 6. As shown, the second substrate side 626 includes the openings 624 with the inner substrate contacts 628, such as conductive metal pads, along each of the openings 624 for connection to the first electrical interconnect 632 of FIG. 6. The second substrate side 626 also includes the outer substrate contacts 630, such as conductive metal pads, for connection to the third electrical interconnect 638 of FIG. 6. The second substrate side 626 also includes the mounting contacts 510.

Referring now to FIG. 8, therein is shown a top view of a mountable integrated circuit package system 800 in a fourth embodiment of the present invention. The top view depicts a package encapsulation 802, such as an epoxy mold compound, having a protrusion 804 and a package cavity 806. The package cavity 806 partially exposes a substrate 808 having mounting contacts 810 and the protrusion 804 within the package cavity 806. The mounting contacts 810 may be formed from electrically conductive materials including tin (Sn), lead (Pb), gold (Au), copper (Cu), or metal alloys.

For illustrative purposes, the mountable integrated circuit package system 800 is shown with the mounting contacts 810 in configurations of an evenly distributed array, although it is understood that the mountable integrated circuit package system 800 may have the mounting contacts 810 in a different configuration. For example, the mounting contacts 810 may be in configurations of a non-evenly distributed array.

Referring now to FIG. 9, therein is shown a cross-sectional view of the mountable integrated circuit package system 800 of FIG. 8 along line 9-9. The cross-sectional view depicts the mountable integrated circuit package system 800 having the package encapsulation 802 formed over a carrier 912, such as a substrate, having mounted thereon a first integrated circuit device 914, such as an integrated circuit die, a flip chip, or a packaged integrated circuit device. A second integrated circuit device 916 is mounted over the first integrated circuit device 914 with a first adhesive 918 such as a die-attach adhesive. The second integrated circuit device 916 includes an inner encapsulation 940 covering the substrate 808 and an integrated circuit die 920.

As illustrated, the substrate 808 may have structural similarities to the substrate 108 of FIG. 3. A first substrate side 922 facing the first integrated circuit device 914 includes inner substrate contacts 928 along an opening 924 of the substrate 808. A second substrate side 926 of the substrate 808, opposing the first substrate side 922, includes outer substrate contacts 930, the mounting contacts 810, with the integrated circuit die 920 attached to the second substrate side 926. A first electrical interconnect 932, such as bond wires, connects the integrated circuit die 920 and the inner substrate contacts 928 through the opening 924. A second electrical interconnect 934, such as a bond wire, connects the outer substrate contacts 930 and the carrier 912. The mounting contacts 810 provided connection to another integrated circuit device (not shown.)

The second integrated circuit device 916 includes the inner encapsulation 940, such as an epoxy molding compound. The inner encapsulation 940 is formed covering the integrated circuit die 920 and the first electrical interconnect 932. The inner encapsulation 940 also fills the opening 924 and covers the first substrate side 922. The inner encapsulation 940 forms the protrusion 804 covering the integrated circuit die 920 over the second substrate side 926.

The package encapsulation 802 partially exposes the second substrate side 926 within the package cavity 806 of the package encapsulation 802. The package encapsulation 802 covers the carrier 912, the first integrated circuit device 914, the second integrated circuit device 916, and the second electrical interconnect 934. The package encapsulation 802 also covers the inner encapsulation 940 with the mounting contacts 810 and the protrusion 804 exposed.

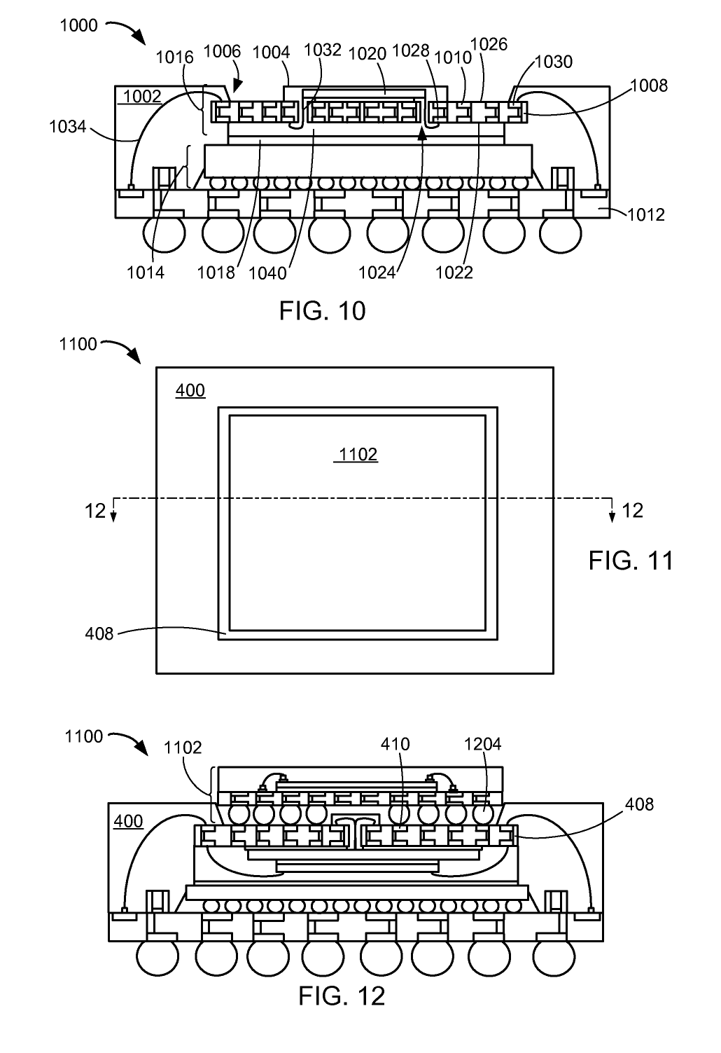

Referring now to FIG. 10, therein is shown a cross-sectional view of a mountable integrated circuit package system 1000 as exemplified by the top view of FIG. 8 in a fifth embodiment of the present invention. The cross-sectional view depicts the mountable integrated circuit package system 1000 having a package encapsulation 1002 formed over a carrier 1012, such as a substrate, having mounted thereon a first integrated circuit device 1014, such as an integrated circuit die, a flip chip, or a packaged integrated circuit device. A second integrated circuit device 1016 is mounted over the first integrated circuit device 1014 with a first adhesive 1018 such as a die-attach adhesive. The second integrated circuit device 1016 includes an inner encapsulation 1040 covering a substrate 1008 having openings 1024 and an integrated circuit die 1020.

As illustrated, the substrate 1008 may have structural similarities to the substrate 508 of FIG. 7. A first substrate side 1022 facing the first integrated circuit device 1014 includes inner substrate contacts 1028 along the openings 1024 of the substrate 1008. A second substrate side 1026 of the substrate 1008, opposing the first substrate side 1022, includes outer substrate contacts 1030, mounting contacts 1010, with the integrated circuit die 1020 attached to the second substrate side 1026. A first electrical interconnect 1032, such as bond wires, connects the integrated circuit die 1020 and the inner substrate contacts 1028 through each of the openings 1024. A second electrical interconnect 1034, such as a bond wire, connects the outer substrate contacts 1030 and the carrier 1012. The mounting contacts 1010 provided connection to another integrated circuit device (not shown.)

The second integrated circuit device 1016 includes the inner encapsulation 1040, such as an epoxy molding compound. The inner encapsulation 1040 is formed covering the integrated circuit die 1020 and the first electrical interconnect 1032. The inner encapsulation 1040 also fills each of the openings 1024 and covers the first substrate side 1022. The inner encapsulation 1040 forms a protrusion 1004 covering the integrated circuit die 1020 over the second substrate side 1026.

The package encapsulation 1002 partially exposes the second substrate side 1026 within a package cavity 1006 of the package encapsulation 1002. The package encapsulation 1002 covers the carrier 1012, the first integrated circuit device 1014, the second integrated circuit device 1016, and the second electrical interconnect 1034. The package encapsulation 1002 also covers the inner encapsulation 1040 with the mounting contacts 1010 and the protrusion 1004 exposed.

Referring now to FIG. 11, therein is shown a top view of an integrated circuit package-on-package system 1100 in an application with the mountable integrated circuit package system 400 of FIG. 4 in a sixth embodiment of the present invention. The integrated circuit package-on-package system 1100 may be formed with other embodiments of the present inventions, such as the mountable integrated circuit package system 100 of FIG. 2, the mountable integrated circuit package system 500 of FIG. 6, the mountable integrated circuit package system 800 of FIG. 9, or the mountable integrated circuit package system 1000 of FIG. 10. As shown, a mounting integrated circuit 1102 is mounted over the substrate 408 of the mountable integrated circuit package system 400.

Referring now to FIG. 12, therein is shown a cross-sectional view of the integrated circuit package-on-package system 1100 along 12-12 of FIG. 11. The mounting integrated circuit 1102 is mounted over the mounting contacts 410 of the substrate 408 of the mountable integrated circuit package system 400. Preferably, mounting interconnects 1204, such as solder balls or conductive pads, on the mounting integrated circuit 1102, mounts over and connect with the mounting contacts 410 of the substrate 408 to provide electrical connection in between.

For illustrative purposes, the integrated circuit package-on-package system 1100 is shown with the mounting integrated circuit 1102 as a packaged integrated circuit, although it is understood that the integrated circuit package-on-package system 1100 may be formed with different types of integrated circuit for the mounting integrated circuit 1102. For example, the mounting integrated circuit 1102 may include multiple integrated circuits, a ball grid array (BGA) device, a 1 and grid array (LGA) device, a quad flat nonleaded (QFN) device, a quad flat package (QFP) device, a bump chip carrier (BCC) device, a flip chip, a passive component, or a combination thereof.

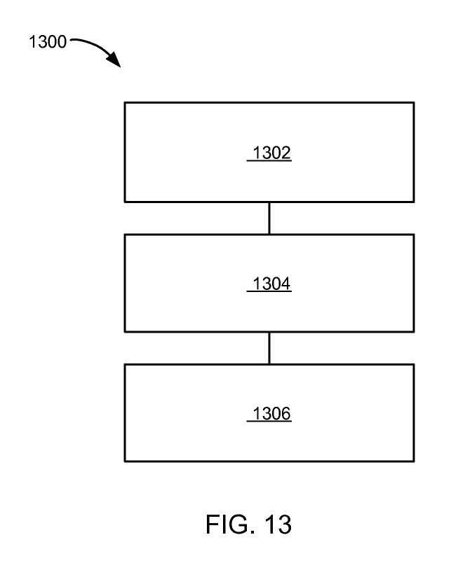

Referring now to FIG. 13, therein shown is a flow chart of a mountable integrated circuit package system 1300 for manufacture of the mountable integrated circuit package system in an embodiment of the present invention. The mountable integrated circuit package system 1300 includes: mounting a first integrated circuit device over a carrier in a block 1302; mounting a second integrated circuit device over the first integrated circuit device includes: attaching the second integrated circuit device to a first substrate side of a substrate, and connecting a first electrical interconnect between the second integrated circuit device and a second substrate side of the substrate through an opening in the substrate in a block 1304; and forming a package encapsulation over the first integrated circuit device and the carrier with the substrate partially exposed in a block 1306.

Yet other important aspects of the embodiments include that it valuably supports and services the historical trend of reducing costs, simplifying systems, and increasing performance.

These and other valuable aspects of the embodiments consequently further the state of the technology to at least the next level.

Thus, it has been discovered that the mountable integrated circuit package system of the present invention furnishes important and heretofore unknown and unavailable solutions, capabilities, and functional aspects for improving reliability in systems. The resulting processes and configurations are straightforward, cost-effective, uncomplicated, highly versatile, and effective, can be implemented by adapting known technologies, and are thus readily suited for efficiently and economically manufacturing integrated circuit package devices.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations that fall within the scope of the included claims. All matters hithertofore set forth herein or shown in the accompanying drawings are to be interpreted in an illustrative and non-limiting sense.

What is claimed is:

1. A mountable integrated circuit package system comprising:
mounting a first integrated circuit device over a carrier;
mounting a second integrated circuit device over the first integrated circuit device includes:
attaching the second integrated circuit device to a first substrate side of a substrate, and
connecting a first electrical interconnect between the second integrated circuit device and a second substrate side of the substrate through an opening in the substrate; and
forming a package encapsulation over the first integrated circuit device and the carrier with the substrate partially exposed.

2. The system as claimed in claim 1 wherein forming the package encapsulation includes:
encapsulating an inner encapsulation, having a protrusion, through the opening, of the second integrated circuit device; and
exposing the protrusion.

3. The system as claimed in claim 1 wherein forming the package encapsulation includes:
encapsulating an inner encapsulation, having protrusions, through openings of the substrate of the second integrated circuit device; and
exposing the protrusions.

4. The system as claimed in claim 1 wherein forming the package encapsulation includes:
encapsulating an inner encapsulation, having a protrusion over an integrated circuit die of the second integrated circuit device and over the first substrate side, with the inner encapsulation in the opening.

5. The system as claimed in claim 1 further comprises mounting an integrated circuit over the substrate.

6. A mountable integrated circuit package system comprising:
mounting a first integrated circuit device on a carrier;
mounting a second integrated circuit device over the first integrated circuit device includes:
attaching the second integrated circuit device to a first substrate side of a substrate,
connecting a first electrical interconnect between the second integrated circuit device and a second substrate side of the substrate through an opening in the substrate, and
connecting a second electrical interconnect between the substrate and the carrier; and
forming a package encapsulation over the first integrated circuit device, the second electrical interconnect, and the carrier with the substrate partially exposed.

7. The system as claimed in claim 6 wherein:
connecting the first electrical interconnect between the second integrated circuit device and the second substrate side of the substrate through the opening in the substrate includes:
connecting the first electrical interconnect through openings in the substrate, and
forming the package encapsulation includes:
encapsulating an inner encapsulation, having a protrusion over an integrated circuit die of the second integrated circuit device and over the first substrate side, with the inner encapsulation in the openings.

8. The system as claimed in claim 6 wherein:
mounting the second integrated circuit device includes:
attaching a first integrated circuit die to the first substrate side,
connecting the first electrical interconnect between the first integrated circuit die and the second substrate side through the opening in the substrate,
mounting a second integrated circuit die to the first integrated circuit die,
connecting the second electrical interconnect between the second integrated circuit die and the first substrate side, and
forming an inner encapsulation, having a protrusion over the second substrate side, and through the opening covering the first integrated circuit die, the second integrated circuit die, the first electrical interconnect, and the second electrical interconnect; and
forming the package encapsulation includes:
encapsulating the inner encapsulation with the protrusion exposed.

9. The system as claimed in claim 6 wherein:
mounting the second integrated circuit device includes:
attaching a first integrated circuit die to the first substrate side,
connecting the first electrical interconnect between the first integrated circuit die and the second substrate side through the openings in the substrate,
mounting a second integrated circuit die to the first integrated circuit die,
connecting the second electrical interconnect between the second integrated circuit die and the first substrate side, and
forming an inner encapsulation, having protrusions over the second substrate side, and through the openings covering the first integrated circuit die, the second integrated circuit die, the first electrical interconnect, and the second electrical interconnect; and
forming the package encapsulation includes:
encapsulating the inner encapsulation with the protrusions exposed.

10. The system as claimed in claim 6 wherein forming the package encapsulation includes exposing the substrate in a package cavity of the package encapsulation.

11. A mountable integrated circuit package system comprising:
a carrier;
a first integrated circuit device over the carrier;
a second integrated circuit device over the first integrated circuit device including:
a substrate having a first substrate side with the second integrated circuit device attached thereto, and
a first electrical interconnect between the second integrated circuit device and a second substrate side of the substrate through an opening in the substrate; and
a package encapsulation over the first integrated circuit device and the carrier with the substrate partially exposed.

12. The system as claimed in claim 11 wherein the package encapsulation encapsulates an inner encapsulation, having a protrusion, of the second integrated circuit device, through the opening with the protrusion exposed.

13. The system as claimed in claim 11 wherein the package encapsulation encapsulates an inner encapsulation, having protrusions, of the second integrated circuit device, through openings with the protrusions exposed.

14. The system as claimed in claim 11 wherein the package encapsulation encapsulates an inner encapsulation, having a protrusion over an integrated circuit die, of the second integrated circuit device, and covers the first substrate side, with the inner encapsulation in the opening.

15. The system as claimed in claim 11 further comprising an integrated circuit over the substrate.

16. The system as claimed in claim 11 wherein:
the first integrated circuit device is mounted on the carrier;
further comprising:
a second electrical interconnect between the substrate and the carrier; and
wherein:
the package encapsulation encapsulates the second electrical interconnect and the carrier.

17. The system as claimed in claim 16 wherein:
the first electrical interconnect is connected between the second integrated circuit device and the second substrate side of the substrate through openings in the substrate; and
the package encapsulation encapsulates an inner encapsulation, having a protrusion over an integrated circuit die, of the second integrated circuit device, and covers the first substrate side, with the inner encapsulation in the openings.

18. The system as claimed in claim 16 wherein:
the second integrated circuit device includes:
a first integrated circuit die attached to the first substrate side, the first electrical interconnect between the first integrated circuit die and the second substrate side through the opening in the substrate,
a second integrated circuit die mounted to the first integrated circuit die,
the second electrical interconnect connected between the second integrated circuit die and the first substrate side, and
an inner encapsulation, having a protrusion over the second substrate side, and through the opening, covering the first integrated circuit die, the second integrated circuit die, the first electrical interconnect, and the second electrical interconnect; and
the package encapsulation includes:
the inner encapsulation encapsulated with the protrusion exposed.

19. The system as claimed in claim 16 wherein:
the second integrated circuit device includes:
the first integrated circuit die attached to the first substrate side,
the first electrical interconnect between the first integrated circuit die and the second substrate side through openings in the substrate,
a second integrated circuit die mounted to the first integrated circuit die,
the second electrical interconnect between the second integrated circuit die and the first substrate side, and
an inner encapsulation, having protrusions over the second substrate side, and through the openings, covering the first integrated circuit die, the second integrated circuit die, the first electrical interconnect, and the second electrical interconnect; and
the package encapsulation includes:
the inner encapsulation encapsulated with the protrusions exposed.

20. The system as claimed in claim 16 wherein the package encapsulation includes a package cavity with the substrate exposed by the package cavity.
